(19) United States
(12) Patent Application Publication
(10) Pub. No.: US 2007/0132065 A1
(43) Pub. Date: Jun. 14, 2007

(54) Paraelectric thin film structure for high frequency tunable device and high frequency tunable device with the same

(76) Inventors: Su Jae Lee, Daejeon-city (KR); Han Cheol Ryu, Seoul (KR); Seung Eon Moon, Daejeon-city (KR); Young Tae Kim, Seoul (KR); Min Hwan Kwak, Daejeon-city (KR); Kwang Yong Kang, Daejeon-city (KR)

Correspondence Address: LADAS & PARRY LLP, 224 SOUTH MICHIGAN AVENUE, SUITE 1600, CHICAGO, IL, 60604, US

(21) Appl. No.: 11/389,761

(22) Filed: Mar. 27, 2006

(30) Foreign Application Priority Data
Dec. 8, 2005 (KR) 10-2005-0120174
Jan. 25, 2006 (KR) 10-2006-0007915

(51) Int. Cl. H01L 29/93; H01L 21/20

(52) U.S. Cl. 257/595; 438/379; 257/E29.344

(57) ABSTRACT

Provided are a paraelectric thin film structure and a high frequency tunable device with the paraelectric thin film structure. The paraelectric thin film structure has a large dielectric constant tuning rate and a low dielectric loss at a high frequency. The paraelectric thin film structure includes a perovskite ABO₃ type paraelectric film formed on an oxide single crystal substrate. The paraelectric film is formed of a material selected from Ba(Zrₓ,Ti₁₋ₓ)O₃, Ba(Hf_{y},Ti_{1-y})O₃, or Ba(Sn_{z},Ti_{1-z})O₃. Instead of the paraelectric film, the paraelectric thin film structure may include a compositionally graded paraelectric film having at least two paraelectric films formed of the selected material by varying the composition ratio x, y, or z. A high-frequency/phase tunable device employing the paraelectric thin film structure can have improved microwave characteristics and high-speed, low-power-consuming, low-cost characteristics.

### CROSS-REFERENCE TO RELATED PATENT APPLICATION

This application claims the benefit of Korean Patent Application Nos. 10-2005-0120174, filed on Dec. 8, 2005 and 10-2006-0007915, filed on Jan. 25, 2006, in the Korean Intellectual Property Office, the disclosures of which are incorporated herein in their entirety by reference.

### BACKGROUND OF THE INVENTION

1. Field of the Invention

The present invention relates to a paraelectric thin film with a perovskite ABO₃ structure and a high frequency tunable device using the paraelectric thin film.

2. Description of the Related Art

Recently, various new services are realized, such as high-speed, high-rate, next-generation broadband broadcastings, communications, internet-based mobile wireless multimedia systems, ubiquitous communications, and sensor systems. Accordingly, development of high-speed, low-power-consuming, low-cost core materials/parts is important for wireless mobile/satellite communication and sensor systems. It is increasingly required to develop ferroelectric thin-materials and devices for providing excellent high frequency characteristics and complementing the merits and demerits of conventional tunable devices formed using semiconductors, micro-electro-mechanical systems (MEMS), magnetic substances, and photonics materials.

High frequency tunable devices using ferroelectric films have advantageous characteristics such as high-speed, low-power-consuming, small-sized, light-weighted, low-cost, large frequency/phase variable, broadband, and system on a chip (S_{O}C) characteristics. In developing such high frequency tunable devices with the ferroelectric films, high frequency dielectric loss, frequency/phase tuning rate, and high driving voltage of the ferroelectric film are main problems. Therefore, ferroelectric films for the high frequency tunable devices should have a high dielectric constant tuning rate, a low dielectric loss, and a low temperature dependency in the dielectric constant. Particularly, what is needed is a paraelectric film having a dielectric constant that does not exhibit a hysteresis characteristic (ferroelectric hysteresis characteristic) with respect to an external voltage input in the operating temperature range of the high frequency device. The ferroelectric hysteresis characteristic is a cause of error signals of the high frequency tunable device, thereby making it difficult to make the high frequency device.

Among various ferroelectric materials, barium-strontium-titanium (Ba_{1-X}Sr_{X})TiO₃ (hereinafter, referred to as BST) is known as an effective thin film material for a high frequency tunable device because of its large dielectric constant tuning rate and low dielectric loss. Therefore, many researches have been performed for improving the dielectric characteristics of the BST thin film and making high frequency tunable devices using the BST film. Particularly, if the BST has a composition ratio of x≧0.4, the BST exhibits paraelectric characteristics at a room temperature. To obtain a BST thin film having a large dielectric constant tuning rate and low dielectric loss, many researches have been performed on doping, film-forming temperature, defect compensation for a Ba/Sr composition ratio, thickness dependency, etc. However, obtaining a BST paraelectric film having characteristics comparable with the dielectric characteristics of a BST single crystal is limited. It is known that the dielectric constant tuning rate and dielectric loss of a BST paraelectric film grown on an oxide single crystal substrate are affected by various factors such as oxygen vacancies, film thickness, crystal grain size, doping elements, Ba/Sr composition ratio, strain/stress in the film, crystallinity of the film, and film forming conditions including temperature, oxygen partial pressure, and growth rate. Particularly, due to large lattice constant mismatch between the oxide single crystal substrate and the BST paraelectric film grown on the oxide single crystal substrate, epitaxial thin layer growth is not easy. This causes a large strain/stress in the paraelectric film, thereby decreasing the dielectric constant tuning rate and increasing the dielectric loss. Thus, high-frequency signal loss increases in the high frequency tunable device having the BST paraelectric film, such that it is difficult to attain devices having superior characteristics.

Therefore, what is needed is a paraelectric film having a large dielectric constant tuning rate and low dielectric loss for a high frequency tunable device having desirable characteristics.

### SUMMARY OF THE INVENTION

The present invention provides a paraelectric thin film structure having a large dielectric constant tuning rate and low dielectric loss for a high frequency tunable device.

The present invention also provides a paraelectric thin film structure having large dielectric constant tuning rate, low dielectric loss, and low temperature dependency in the dielectric constant, for a high frequency tunable device.

The present invention further provides a high frequency tunable device having improved microwave characteristics and high-speed, low-power-consuming, and low-cost characteristics by using a paraelectric thin film structure having a large dielectric constant tuning rate and low dielectric loss.

According to an aspect of the present invention, there is provided a paraelectric thin film structure for a high frequency tunable device, the paraelectric thin film structure including: a paraelectric film having a perovskite ABO₃ structure, formed on an oxide single crystal substrate.

The oxide single crystal substrate may be formed of a material selected from the group consisting of MgO, LaAl₂O₃, and Al₂O₃ substrates. The paraelectric film may be formed of a material selected from the group consisting of Ba(Zrₓ,Ti₁₋ₓ)O₃(0<x<1), Ba(Hf_{y},Ti_{1-y})O₃(0<y<1), and Ba(Sn_{z},Ti_{1-z})O₃(0<z<1). The Ba(Zrₓ,Ti₁₋ₓ)O₃ may have a composition ratio of 0.2≦x<1. The Ba(Hf_{y},Ti_{1-y})O₃ may have a composition ratio of 0.2≦y<1. The Ba(Sn_{z},Ti_{1-z})O₃ has a composition ratio of 0.1≦z<1.

According to another aspect of the present invention, there is provided a paraelectric thin film structure for a high frequency tunable device, the paraelectric thin film structure including: an oxide single crystal substrate; and a compositionally graded paraelectric film formed on the oxide single crystal substrate using a material selected from the group consisting of Ba(Zrₓ,Ti₁₋ₓ)O₃(0<x<1), Ba(Hf_{y},Ti_{1-y})O₃(0<y<1), and Ba(Sn_{z},Ti_{1-z})O₃(0<z<1). The compositionally graded paraelectric film may include at least two paraelectric films each having different a composition ratio of x, y, or z and a perovskite ABO₃ structure. The epitaxial paraelectric films may be grown on the oxide single crystal substrate by pulsed laser ablation, RF magnetron sputtering, chemical vapor deposition, atomic layer deposition, etc.

According to further another aspect of the present invention, there is provided a high frequency tunable device including: an oxide single crystal substrate; a perovskite ABO₃ type paraelectric film or a compositionally graded paraelectric film having a plurality of perovskite ABO₃ type paraelectric films formed on the oxide single crystal substrate; and an electrode formed on the paraelectric film.

The paraelectric film may be formed of a material selected from the group consisting of Ba(Zrₓ,Ti₁₋ₓ)O₃(0<x1), Ba(Hf_{y},Ti_{1-y})O₃(0<y<1), and Ba(Sn_{z},Ti_{1-z})O₃(0<z<1), and the composition ratios may be 0.2≦x<1, 0.2≦y<1, and 0.1≦z<1. The electrode may be formed of at least one material selected from the group consisting of Au, Ag, Al, Cu, Cr, and Ti. The high frequency tunable device may be one device selected from the group consisting of a voltage control tunable capacitor, a tunable resonator, a tunable filter, a phase shifter, a voltage control oscillator, a duplexer, and a tunable divider.

According to the present invention, the paraelectric thin film structure for the high frequency tunable device has a small lattice constant mismatch between the paraelectric film and the oxide single crystal substrate so that the paraelectric thin film structure can have a large dielectric constant tuning rate and low dielectric loss with respect to an external voltage input. Further, the high frequency tunable device can have improved high-frequency response characteristics by employing the paraelectric thin film structure, so that the high frequency tunable device can be usefully used in communication and sensor systems for high-speed, high-rate, next-generation broadband broadcastings, communications, and internet-based mobile wireless multimedia services.

### BRIEF DESCRIPTION OF THE DRAWINGS

The above and other features and advantages of the present invention will become more apparent by describing in detail exemplary embodiments thereof with reference to the attached drawings in which:

FIG. 1 is a sectional view of a paraelectric thin film structure including a paraelectric film formed on an oxide single crystal substrate for a high frequency tunable device according to the present invention;

FIG. 2 is a sectional view of a compositionally graded paraelectric thin film structure formed on an oxide single crystal substrate and including a plurality of paraelectric films for a high frequency tunable device according to the present invention;

FIG. 3 is a graph showing a θ-2θ X-ray diffraction pattern of a paraelectric Ba(Zrₓ,Ti₁₋ₓ)O₃ thin film formed on an oxide single crystal substrate for a high frequency tunable device according to the present invention;

FIG. 4 is a graph showing a θ-2θ X-ray diffraction pattern of a paraelectric Ba(Sn_{z},Ti_{1-z})O₃ thin film formed on an oxide single crystal substrate for a high frequency tunable device according to the present invention;

FIG. 5 is a scanning electron microscope (SEM) photograph showing a cross section and a surface of a paraelectric Ba(Zrₓ,Ti₁₋ₓ)O₃ thin film structure formed on an oxide single crystal substrate for a high frequency tunable device according to the present invention;

FIG. 6 is an SEM photograph showing a cross section and a surface of a paraelectric Ba(Sn_{z},Ti_{1-z})O₃ thin film structure formed on an oxide single crystal substrate for a high frequency tunable device according to the present invention;

FIG. 7 is a perspective view of a voltage tunable capacitor as a high frequency tunable device including a paraelectric thin film structure according to the present invention;

FIG. 8 is a capacitance-voltage graph of a voltage tunable capacitor including Ba(Sn_{z},Ti_{1-z})O₃ according to the present invention;

FIG. 9 is a dielectric loss versus voltage graph of a voltage tunable capacitor including Ba(Sn_{z},Ti_{1-z})O₃ according to the present invention;

FIG. 10 is a capacitance-voltage graph of a voltage tunable capacitor including Ba(Zrₓ,Ti₁₋ₓ)O₃ according to the present invention;

FIG. 11 is a dielectric loss versus voltage graph of a voltage tunable capacitor including Ba(Zrₓ,Ti₁₋ₓ)O₃ according to the present invention;

FIG. 12 is a perspective view of a coplanar waveguide (CPW) phase shifter as a high frequency tunable device including a paraelectric thin film structure according to the present invention;

FIG. 13 is a graph showing phase shift with respect to frequency and voltage in a CPW phase shifter including Ba(Sn_{z},Ti_{1-z})O₃ according to the present invention;

FIG. 14 is a graph showing insertion loss with respect to frequency and voltage in a CPW phase shifter including Ba(Sn_{z},Ti_{1-z})O₃ according to the present invention;

FIG. 15 is a graph showing phase shift with respect to frequency and voltage in a CPW phase shifter including Ba(Zrₓ,Ti₁₋ₓ)O₃ according to the present invention; and

FIG. 16 is a graph showing insertion loss with respect to frequency and voltage in a CPW phase shifter including Ba(Zrₓ,Ti₁₋ₓ)O₃ according to the present invention.

### DETAILED DESCRIPTION OF THE INVENTION

The present invention will now be described more fully with reference to the accompanying drawings, in which exemplary embodiments of the invention are shown.

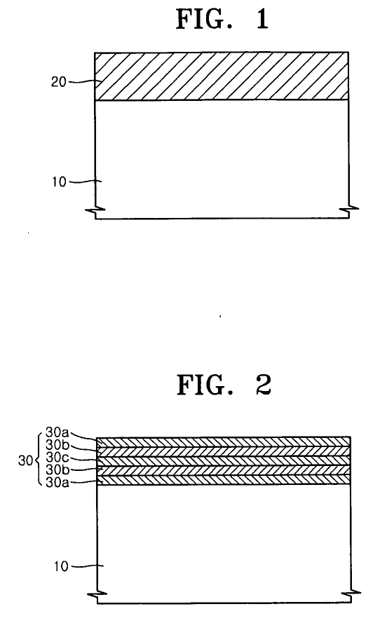

FIG. 1 is a sectional view of a paraelectric thin film structure including a paraelectric film formed on an oxide single crystal substrate for a high frequency tunable device according to the present invention, and FIG. 2 is a sectional view of a compositionally graded paraelectric thin film structure formed on an oxide single crystal substrate and including a plurality of paraelectric films for a high frequency tunable device according to the present invention.

Referring to FIG. 1, a paraelectric thin film structure for a high frequency tunable device of the present invention includes a perovskite ABO₃ type paraelectric film 20 formed on an oxide single crystal substrate 10 to a predetermined thickness. The oxide single crystal substrate 10 includes MgO, LaAl₂O₃, or Al₂O₃ single crystal. The paraelectric film 20 includes one of Ba(Zrₓ,Ti₁₋ₓ)O₃(0<x<1), Ba(Hf_{y},Ti_{1-y})O₃(0<y<1), or Ba(Sn_{z},Ti_{1-z})O₃(0<z<1), and the composition ratios may be 0.2≦x<1, 0.2≦y<1, and 0.1≦z<1, respectively. The oxide single crystal substrate 10 may have a thickness of 0.2 to 1 mm, and the paraelectric film 20 may have a thickness of about 0.05 to 5 μm.

Referring to FIG. 2, a paraelectric thin film structure for a high frequency tunable device of the present invention includes a compositionally graded paraelectric film 30 formed on an oxide single crystal substrate 10 and having a plurality of paraelectric films. The compositionally graded paraelectric film 30 includes a combination of at least two paraelectric films that are formed by using one material selected from Ba(Zrₓ,Ti₁₋ₓ)O₃(0<x<1), Ba(Hf_{y},Ti_{1-y})O₃(0<y<1), or Ba(Sn_{z},Ti_{1-z})O₃(0<z<1) and by varying the composition ratio of the selected material. For example, the compositionally graded paraelectric film 30 may include a first paraelectric film 30a having Ba(Zr_{0.3},Ti_{0.7})O₃, a second paraelectric film 30b having Ba(Zr_{0.4},Ti_{0.6})O₃, and a third paraelectric film 30c having Ba(Zr_{0.5},Ti_{0.5})O₃, and the first, second, and third paraelectric films 30a, 30b, and 30c may be formed on the oxide single crystal substrate 10 in the following order: first paraelectric film 30a, second paraelectric film 30b, third paraelectric film 30c, second paraelectric film 30b, and first paraelectric film 30a. Each of the paraelectric films 30a, 30b, and 30c may have a thickness of 0.01 to 1 μm. The compositionally graded paraelectric film 30 may have a thickness of about 0.1 to 1 μm respectively.

The paraelectric films 20, 30a, 30b, and 30c, which are formed on the substrate 10 that is generally used for a high frequency tunable device, have advantages such as a high dielectric constant tuning rate and a low dielectric loss. Further, the paraelectric films 30a, 30b, and 30c formed in a multiple manner for the compositionally graded paraelectric film 30 have different phase transition points (temperatures), such that temperature dependency of dielectric constant can be reduced on the average.

The paraelectric thin film structure for a high frequency tunable device of the present invention has good dielectric characteristics, and lattice constant mismatch is small between the oxide single crystal substrate 10 and the paraelectric film 20 (or the compositionally graded paraelectric film 30). For example, when a MgO(100) single crystal substrate is used for the oxide single crystal substrate 10, and Ba(Zrₓ,Ti₁₋ₓ)O₃(0.2≦x<1), Ba(Hf_{y},Ti_{1-y})O₃(0.2≦y<1), and Ba(Sn_{z},Ti_{1-z})O₃(0.1≦z<1) are used for forming the paraelectric film 20 on the oxide single crystal substrate 10, the lattice mismatch between the oxide single crystal substrate 10 and the paraelectric film 20 becomes 4.1%, 4.0%, and 4.3%, respectively (see Table 1 below).

TABLE 1

| | | | Lattice | |
|---|---|---|---|---|
| | | Crystal | Constant | Lattice |
| | | Structure | (Å) | Mismatch |
| Substrate | MgO | Cubic | 4.213 | 0 |
| Type of | Ba(Zrₓ, Ti₁₋ₓ)O₃ | Cubic | 4.042 | −4.1% |
| Paraelectric | (x > 0.2) | | | |
| Thin Film | Ba(Hfₓ, Ti₁₋ₓ)O₃ | Cubic | 4.045 | −4.0% |
| | (x > 0.2) | | | |
| | Ba(Snₓ, Ti₁₋ₓ)O₃ | Cubic | 4.03 | −4.3% |
| | (x > 0.1) | | | |

In fabricating the paraelectric thin film structure for a high frequency tunable device, the paraelectric film 20 or the compositionally graded paraelectric film 30 is epitaxially formed on the oxide single crystal substrate 10. The epitaxial growth can be performed using various methods, such as pulsed laser ablation, RF magnetron sputtering, chemical vapor deposition, and atomic layer deposition.

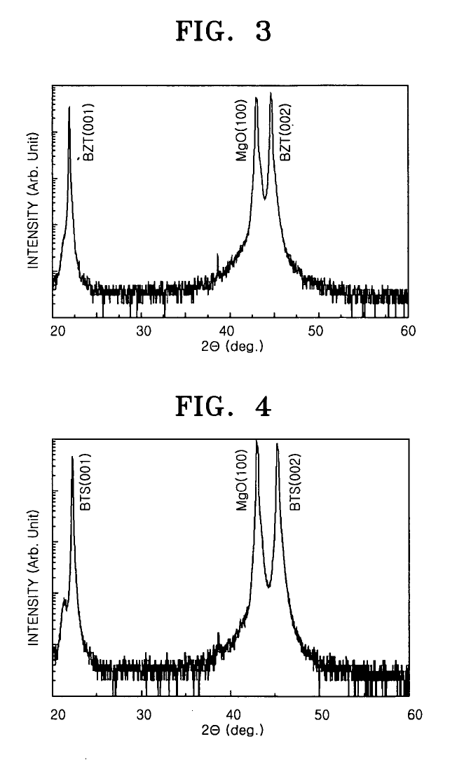

FIG. 3 is a graph showing a θ-2θ X-ray diffraction pattern of a paraelectric Ba(Zrₓ,Ti₁₋ₓ)O₃ thin film for a high frequency tunable device according to the present invention, and FIG. 4 is a graph showing a θ-2θ X-ray diffraction pattern of a paraelectric Ba(Sn_{z},Ti_{1-z})O₃ thin film for a high frequency tunable device according to the present invention.

The θ-2θ X-ray diffraction pattern shown in FIG. 3 is obtained from a paraelectric Ba(Zrₓ,Ti₁₋ₓ)O₃ (hereinafter, referred to as “BZT”) thin film formed on a MgO(100) single crystal substrate using a pulsed laser ablation method. The paraelectric BZT film is grown at a temperature of 750° C. and oxygen pressure of 200 mTorr. Referring to FIG. 3, the paraelectric BZT film exhibits x-ray peaks at (001) and (002) planes. Therefore, it can be known that an epitaxial paraelectric BZT film is formed on a MgO(100) single crystal substrate.

The θ-2θ X-ray diffraction pattern shown in FIG. 4 is obtained from a paraelectric Ba(Sn_{z},Ti_{1-z})O₃ (hereinafter, referred to as “BTS”) thin film formed on a MgO(100) single crystal substrate using a pulsed laser ablation method under the same conditions as given in FIG. 3. Referring to FIG. 4, the paraelectric BTS film also exhibits x-ray peaks at (001) and (002) planes, and thus it can be known that an epitaxial paraelectric BTS film is formed on a MgO(100) single crystal substrate.

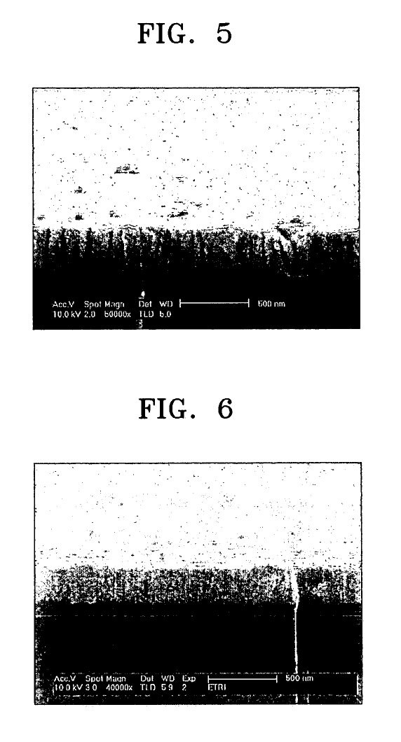

FIG. 5 is a scanning electron microscope (SEM) photograph showing a cross section and a surface of a paraelectric BST thin film structure for a high frequency tunable device according to the present invention, FIG. 6 is an SEM photograph showing a cross section and a surface of a paraelectric BTS thin film structure for a high frequency tunable device according to the present invention.

For the evaluation shown in FIGS. 5 and 6, the paraelectric thin film structures of FIGS. 3 and 4 are used, respectively. Referring to FIGS. 5 and 6, the paraelectric BZT and BTS thin films include crystal grains having a fine columnar structure.

Meanwhile, the paraelectric thin film structure of the present invention has a large dielectric constant tuning rate and a low dielectric loss, so that a high frequency tunable device capable of frequency and phase tunings can be fabricated to have good high-frequency characteristics.

The high frequency tunable device of the present invention is a frequency or phase tunable device that has better characteristics than conventional mechanical or electrical tunable devices.

Examples of the high frequency tunable device of the present invention include a voltage tunable capacitor, a phase shifter, a tunable resonator, a tunable filter, a voltage control tunable oscillator, a duplexer, and a tunable divider. Hereinafter, a voltage tunable capacitor and a coplanar waveguide (CPW) type phase shifter, in which metal electrodes are properly formed on a paraelectric BZT film or a paraelectric BTS film, will be described as examples of the high frequency tunable device.

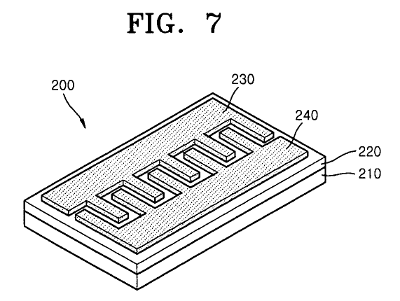

FIG. 7 is a perspective view of a voltage tunable capacitor 200 selected as an example of the high frequency tunable device including the paraelectric thin film structure according to the present invention.

Referring to FIG. 7, the voltage tunable capacitor 200 includes a perovskite ABO₃ type paraelectric film 220 deposited on a MgO(100) single crystal substrate 210. Further, metal electrodes 230 and 240 are formed on the paraelectric film 220. The voltage tunable capacitor 200 can be used for microwave and millimeter-wave tunable circuit such as a tunable filter, a tunable resonator, a phase shifter for military and commercial communication systems applications. The high frequency tunable device shown in FIG. 7 can be easily fabricated through a general photolithography process. For example, the perovskite ABO₃ type paraelectric film 220 can be formed on the MgO(100) single crystal substrate 210 by pulsed laser ablation, and then the metal electrodes 230 and 240 can be formed on the paraelectric film 220. The metal electrodes 230 and 240 may be patterned from a single metal layer formed of a metal selected from various metals such as Au, Ag, Al, and Cu. Alternatively, the metal electrodes 230 and 240 may be formed into a multiple layer structure such as Au/Cr, Au/Ti, Ag/Cr, Ag/Ti, Al/Cr, or Al/Ti multiple layer structure by depositing a thin Cr or Ti adhesion layer on the paraelectric film 220, and by forming a metal layer on the thin adhesion layer to a thickness approximately three times larger than a microwave skin depth using a metal selected from various metals such as Au, Ag, and Cu.

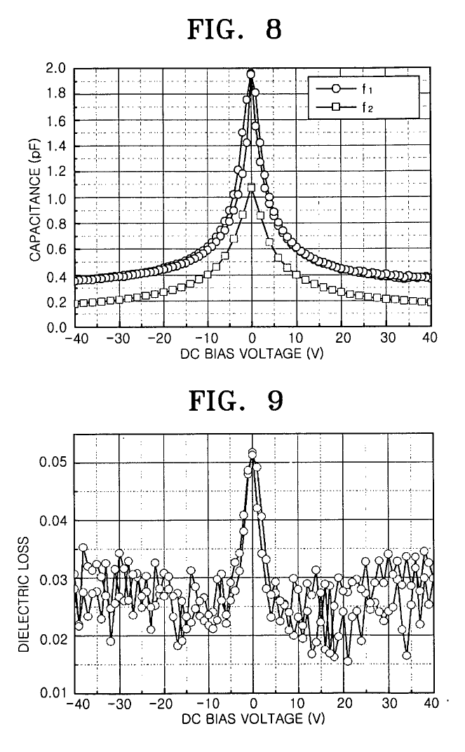

FIG. 8 is a capacitance-voltage graph of a voltage tunable capacitor including a paraelectric BTS film according to the present invention, and FIG. 9 is a dielectric loss versus voltage graph of a voltage tunable capacitor including a paraelectric BTS film according to the present invention.

For the evaluation shown in FIGS. 8 and 9, a voltage tunable capacitor 200 (refer to FIG. 7) is fabricated using a paraelectric BTS film 220 (refer to FIG. 7). As the voltage to the voltage tunable capacitor 200 varies, the electric capacitance and dielectric loss of the voltage tunable capacitor 200 also vary. According to the variation of an applied DC bias voltage between metal electrodes 230 and 240 (refer to FIG. 7) formed on a top of the voltage tunable capacitor 200, the dielectric constant and dielectric loss of the paraelectric BTS film 220 vary, and thus the electric capacitance of the voltage tunable capacitor 200 varies. Therefore, when the voltage tunable capacitor 200 is used for a variable filter or a phase shifter, the frequency/phase of RF signal can be changed.

Referring to FIGS. 8 and 9, when the capacitance-voltage characteristic of the voltage tunable capacitor 200 having the paraelectric BTS film 220 is measured at 100 kHz (f1) and 10 GHz (f2), a typical paraelectric characteristic is observed without hysteresis. Further, when the DC bias voltage to the voltage tunable capacitor 200 varies from 0 through 40 V, the electric capacitance (or dielectric constant) tuning rate [{C(0V)−C(40V)}/C(0V)] is more than 83%, and the dielectric loss is 0.02 to 0.052.

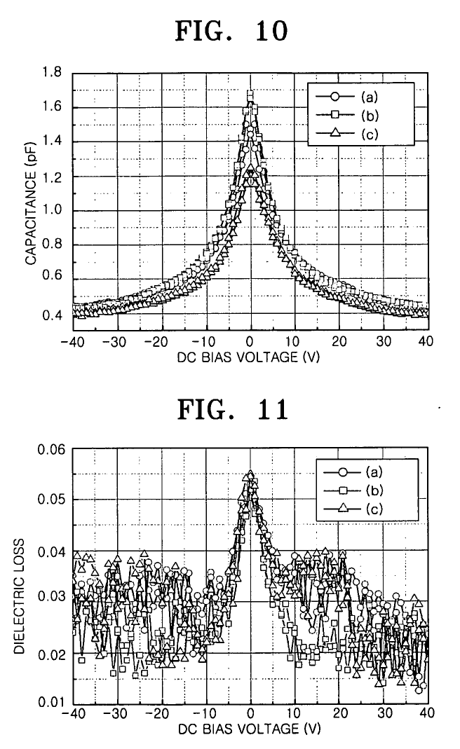

FIG. 10 is a capacitance-voltage graph of a voltage tunable capacitor including a paraelectric BZT film according to the present invention, and FIG. 11 is a dielectric loss versus voltage graph of a voltage tunable capacitor including a paraelectric BZT film according to the present invention.

For the evaluation shown in FIGS. 10 and 11, a voltage tunable capacitor 200 (refer to FIG. 7) having a paraelectric BZT film 220 (refer to FIG. 7) is used while varying the composition ratio of Zr. The electric capacitance and dielectric loss of the voltage tunable capacitor 200 are evaluated while varying a voltage to the voltage tunable capacitor 200.

Referring to FIGS. 10 and 11, (a), (b), and (c) denote the composition ratios of Zr: 0.20, 0.25, and 0.30, respectively. The capacitance-voltage characteristic of the voltage tunable capacitor 200 is measured at 100 kHz, and the measured result shows a typical paraelectric characteristic substantially without hysteresis. When a DC bias voltage to the voltage tunable capacitor 200 varies from 0 through 40 V, the electric capacitance (or dielectric constant) tuning rate [{C(0V)−C(40V)}/C(0V)] is more than 70%, and the dielectric loss is 0.02 to 0.054.

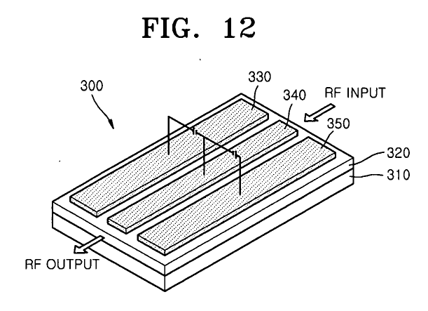

FIG. 12 is a perspective view of a CPW phase shifter 300 selected as an example of a high frequency tunable device including a paraelectric thin film structure according to the present invention.

The CPW phase shifter 300 includes an oxide single crystal substrate 310 and a perovskite ABO₃ type paraelectric film 320 formed on the oxide single crystal substrate 310. The CPW phase shifter 300 further includes a signal transmitting line 340 and ground metal electrode 330 and 350 on the paraelectric film 320.

The CPW phase shifter 300 can be connected to each radiation element of a phased array antenna as a core component enabling switching and scanning/steering of electron beams. Further, since the CPW phase shifter 300 provides high-speed, low-power-consuming, low-cost, small-sized, high-performance electric scanning, the size, weight, and cost of the phased array antenna can be reduced. Furthermore, since the beam phase of the phased array antenna can be adjusted only using a micro controller and a voltage amplifier without mechanical/physical rotation, a high-frequency, paraelectric, electric-scanning phased array antenna can be realized. The CPW phase shifter 300 can be used as a core component of a phased array antenna that operates in microwave and millimeter-wave bands for military and commercial communication system applications.

The paraelectric phase shifter of the present invention is not limited to the CPW type structure. The paraelectric phase shifter can be embodied in different types such as loaded line, coupled microstripline, and reflection types.

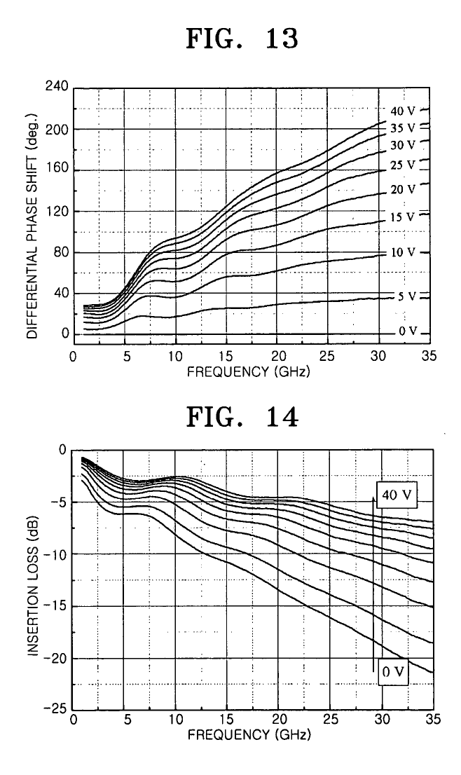

FIG. 13 is a graph showing phase shift with respect to frequency and voltage in a CPW phase shifter including a paraelectric BTS film according to the present invention, and FIG. 14 is a graph showing insertion loss with respect to frequency and voltage in a CPW phase shifter including a paraelectric BTS film according to the present invention.

For the evaluation shown in FIGS. 13 and 14, the CPW phase shifter 300 of FIG. 12 including the paraelectric BTS film 320 on the MgO single crystal substrate 310 is used. The signal transmitting line of the CPW phase shifter 300 is set to 3 mm. Differential phase shift and insertion loss of the CPW phase shifter 300 are evaluated with respect to frequency and DC bias voltage applied to the CPW phase shifter 300.

Referring to FIGS. 13 and 14, the differential phase shift denote a phase difference between 0 V and 40 V applied to the CPW phase shifter 300, and it is related with a dielectric constant tuning rate of the paraelectric BTS film 320. The larger the dielectric constant tuning rate becomes, the larger the differential phase shift becomes. When the CPW phase shifter 300 is used in a system such as a phased array antenna, requiring phase shift is generally 360 degrees although it can vary according to application systems. When a DC bias voltage of 40 V is applied to the CPW phase shifter 300, the differential phase shift is 85 degrees and the insertion loss is −8.0 to −2.5 dB at 10 GHz. This good phase shift characteristic of the CPW phase shifter 300 results from the good dielectric characteristic of the paraelectric BTS paraelectric film 320.

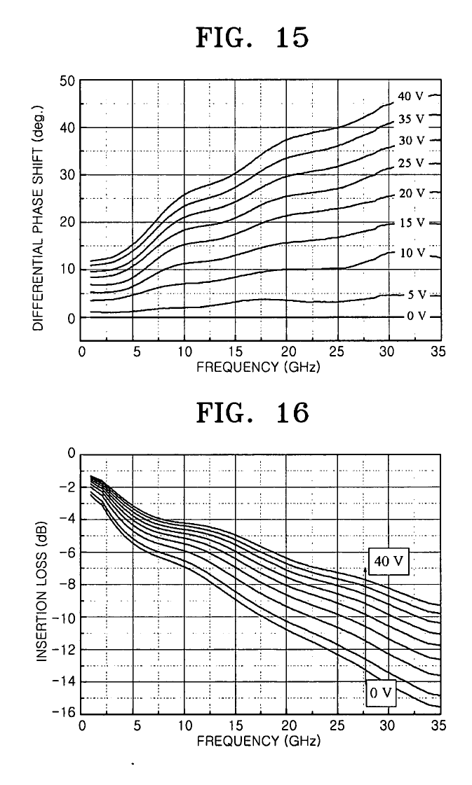

FIG. 15 is a graph showing phase shift with respect to frequency and voltage in a CPW phase shifter including a paraelectric BZT film according to the present invention, and FIG. 16 is a graph showing insertion loss with respect to frequency and voltage in a CPW phase shifter including a paraelectric BZT film according to the present invention.

For the evaluations shown in FIGS. 15 and 16, a paraelectric BZT film 320 (refer to FIG. 12) and a 3-mm signal transmitting line are used in the CPW phase shifter 300 (refer to FIG. 12). FIGS. 15 and 16 respectively show differential phase shift and insertion loss of the CPW phase shifter 300 with respect to a frequency and a DC bias voltage applied to the CPW phase shifter 300.

Referring to FIGS. 15 and 16, the CPW phase shifter 300 used for the test includes paraelectric BZT film 320 formed on a MgO single crystal substrate 310 (refer to FIG. 12) by pulsed laser deposition. When a DC bias voltage of 40 V is applied to the CPW phase shifter 300, the differential phase shift is 26 degrees, and the insertion loss is −7.0 to −4.2 dB at 10 GHz.

While the present invention has been particularly shown and described with reference to exemplary embodiments thereof, it will be understood by those of ordinary skill in the art that various changes in form and details may be made therein without departing from the spirit and scope of the present invention. For example, the voltage tunable capacitor and the CPW phase shifter are described as non-limiting embodiments of the present invention. The present invention can be applied to various frequency/phase tunable devices that use the paraelectric thin film structure and operate in microwave and millimeter-wave bands.

The paraelectric thin film structure of the present invention includes the oxide single crystal substrate and the paraelectric film formed on the oxide single crystal substrate and having a perovskite ABO₃ structure such as Ba(Zrₓ,Ti₁₋ₓ)O₃(0<x<1), Ba(Hf_{y},Ti_{1-y})O₃(0<y<1), or Ba(Sn_{z},Ti_{1-z})O₃(0<z<1). Alternatively, the paraelectric thin film structure of the present invention includes the compositionally graded paraelectric film in stead of the paraelectric film, and the compositionally graded paraelectric film has a plurality of paraelectric films that have different composition ratios. Therefore, the paraelectric thin film structure is suitable for high frequency tunable devices having good characteristics. The paraelectric thin film structure has a large dielectric constant tuning rate and a small dielectric loss with respect to a voltage input, so that the high frequency tunable device employing the paraelectric thin film structure can have improved high frequency response characteristics. Further, when the paraelectric thin film structure is used in communication and sensor systems for high-speed, high-rate next-generation broadband broadcasting, communication, and internet-based mobile wireless multimedia services, high-speed, low-power-consuming, low-cost, high-sensitive wireless communication can be realized. Particularly, the high frequency tunable device using the paraelectric thin film structure of the present invention, such as the voltage tunable capacitor, the tunable filter, and the phase shifter, can be widely used for military and commercial wireless communication systems operating in microwave and millimeter-wave bands.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A paraelectric thin film structure for a high frequency tunable device, comprising:
an oxide single crystal substrate; and
a paraelectric film formed on the oxide single crystal substrate using a material selected from the group consisting of Ba(Zrₓ,Ti₁₋ₓ)O₃(0<x<1), Ba(Hf_{y},Ti_{1-y})O₃(0<y<1), and Ba(Sn_{z},Ti_{1-z})O₃(0<z<1).

2. The paraelectric thin film structure of claim 1, wherein the oxide single crystal substrate is formed of a material selected from the group consisting of MgO, LaAl₂O₃, and Al₂O₃.

3. The paraelectric thin film structure of claim 1, wherein the Ba(Zrₓ,Ti₁₋ₓ)O₃ has a composition ratio of 0.2≦x<1.

4. The paraelectric thin film structure of claim 1, wherein the Ba(Hf_{y},Ti_{1-y})O₃ has a composition ratio of 0.2≦y<1.

5. The paraelectric thin film structure of claim 1, wherein the Ba(Sn_{z},Ti_{1-z})O₃ has a composition ratio of 0.1≦z<1.

6. The paraelectric thin film structure of claim 1, wherein the oxide single crystal substrate has a thickness of 0.1˜1 mm.

7. The paraelectric thin film structure of claim 1, wherein the paraelectric film has a thickness of 0.05˜5 μm.

8. A paraelectric thin film structure for a high frequency tunable device, comprising:
an oxide single crystal substrate; and
a compositionally graded paraelectric film formed on the oxide single crystal substrate using a material selected from the group consisting of Ba(Zrₓ,Ti₁₋ₓ)O₃(0<x<1), Ba(Hf_{y},Ti_{1-y})O₃(0<y<1), and Ba(Sn_{z},Ti_{1-z})O₃(0<z<1),
wherein the compositionally graded paraelectric film includes at least two paraelectric films each having different composition ratio x, y, or z.

9. The paraelectric thin film structure of claim 8, wherein the oxide single crystal substrate is formed of a material selected from the group consisting of MgO, LaAl₂O₃, and Al₂O₃.

10. The paraelectric thin film structure of claim 8 or 9, wherein the Ba(Zrₓ,Ti₁₋ₓ)O₃ has a composition ratio of 0.2≦x<1.

11. The paraelectric thin film structure of claim 8 or 9, wherein the Ba(Hf_{y},Ti_{1-y})O₃ has a composition ratio of 0.2≦y<1.

12. The paraelectric thin film structure of claim 8 or 9, wherein the Ba(Sn_{z},Ti_{1-z})O₃ has a composition ratio of 0.1≦z<1.

13. The paraelectric thin film structure of claim 8, wherein the compositionally graded paraelectric film has a thickness of 0.05 to 5 μm.

14. A high frequency tunable device comprising:
an oxide single crystal substrate;
a paraelectric film formed on the oxide single crystal substrate using a material selected from the group consisting of Ba(Zrₓ,Ti₁₋ₓ)O₃(0<x1), Ba(Hf_{y},Ti_{1-y})O₃(0<y<1), and Ba(Sn_{z},Ti_{1-z})O₃(0<z<1); and
at least one electrode formed on the paraelectric film.

15. The high frequency tunable device of claim 14, wherein the oxide single crystal substrate is formed of a material selected from the group consisting of MgO, LaAl₂O₃, and Al₂O₃.

16. The high frequency tunable device of claim 14, wherein the paraelectric film is a compositionally graded paraelectric film formed of a material selected from the group consisting of Ba(Zrₓ,Ti₁₋ₓ)O₃(0<x<1), Ba(Hf_{y},Ti_{1-y})O₃(0<y<1), and Ba(Sn_{z},Ti_{1-z})O₃(0<z<1), the compositionally graded paraelectric film including at least two paraelectric films each having different composition ratio x, y, or z.

17. The high frequency tunable device of claim 14, wherein the Ba(Zrₓ,Ti₁₋ₓ)O₃ has a composition ratio of 0.2≦x<1.

18. The high frequency tunable device of claim 14, wherein the Ba(Hf_{y},Ti_{1-y})O₃ has a composition ratio of 0.2≦y<1.

19. The high frequency tunable device of claim 14, wherein the Ba(Sn_{z},Ti_{1-z})O₃ has a composition ratio of 0.1≦z<1.

20. The high frequency tunable device of claim 14, wherein the electrode is formed of at least one material selected from the group consisting of Au, Ag, Al, Cu, Cr, and Ti.

21. The high frequency tunable device of claim 14, wherein the high frequency tunable device is one device selected from the group consisting of a voltage tunable capacitor, a tunable resonator, a tunable filter, a phase shifter, a voltage control oscillator, a duplexer, and a tunable divider.
